(19) United States
(12) Patent Application Publication
(10) Pub. No.: US 2008/0087321 A1
(43) Pub. Date: Apr. 17, 2008

(54) PHOTOVOLTAIC ARRAY FOR CONCENTRATED SOLAR ENERGY GENERATOR

(76) Inventor: Zalman Schwartzman, Rehovot (IL)

Correspondence Address: David Klein;DEKEL PATENT LTD., Beit HaRof'im, 18 Menuha VeNahala Street, Room 27, REHOVOT, IL

(21) Appl. No.: 11/759,255

(22) Filed: Jun. 7, 2007

(30) Foreign Application Priority Data
Jun. 29, 2006 (IL) 176619

(51) Int. Cl. H01L 31/052; B29C 33/42

(52) U.S. Cl. 136/246; 249/187.1

(57) ABSTRACT

An extensive photovoltaic array for generating electric power from concentrated solar radiation, formed of an extensive planar structural grid wherein a multitude of power generating modules are installed, said structural grid being positioned by a primary servomechanism to keep incident solar radiation perpendicular to the plane of the array at all times.

### FIELD OF THE INVENTION

This invention relates to a photovoltaic power generating module, data communication method between each module and a central controller, module alignment methods, module power conversion and a heat sink for cooling each photovoltaic cell within the module. The module is part of a large concentrated photovoltaic solar energy generator array.

### BACKGROUND OF THE INVENTION

The invention relates to the generation of photovoltaic electric power from concentrated solar radiation, and more particularly to large sun tracking panels having an array of concentrated photovoltaic power generating modules. See, e.g., U.S. Pat. No. 5,125,983.

Solar energy conversion modules that convert sunlight to electrical power typically employ photovoltaic cells that directly convert sunlight to electrical energy.

Concentrating methods for increasing the solar illumination intensity on photovoltaic cell are usually employed. Such methods include using concentrator lenses and/or reflectors to focus the sun on the cell. See, e.g., U.S. Pat. No. 6,020,554 which utilizes a Fresnel lens in combination with reflectors closely mounted to the photovoltaic cell.

Tracking mechanisms have been developed to keep the lens axis directed to the sun at all times during the day. See, e.g., U.S. Pat. Nos. 4,628,142 and 4,498,456.

The photovoltaic cell is considered to be the most expensive component of a solar energy converter. Increasing the solar illumination intensity with concentrators is considered a very promising cost reduction design approach. It is common to design multi module arrays on two axis tracking panels, each module is usually designed with rectangular shape matching a rectangular lens that allow maximum panel area utilization for collecting the solar energy. See, e.g., U.S. Pat. No. 5,125,983.

The amount of electrical energy generated by the cell is relative to the intensity of solar illumination the photovoltaic cell absorbs. Several research groups showed that when concentrated solar illumination is implemented with specially designed photovoltaic cells, the conversion efficiency can increase above what is achievable with non concentrated designs, reaching levels of 30% and higher.

The concentrated photovoltaic cells are relatively small, thin, rectangular or square semiconductor chips. See, e.g. Spectrolab Inc. (a Boeing company) publication “photovoltaic products” describing “Triple Junction Concentrator Solar Cells”. These cells are designed for concentration ratio of 200-400 suns with efficiency greater than 30%. Their active area is square and they are available in two sizes: 10×10 and 5×5 millimeters.

As disclosed in these publications, a typical concentrated photovoltaic array is constructed of a set of multiple power generating modules. Each module has a multiple lens assembly mounted in rectangular metal housing, each lens is concentrating the solar radiation on a photovoltaic cell mounted on a heat sink and having electrical connections to transfer the electrical energy to a power grid.

Each module is mounted on an extensive sun tracking structural grid forming a coplanar multi module photovoltaic power generating array having substantial extent in both X and Y directions.

The structural grid is defined by a multiplicity of structural members connected to one another at angles and defining spaces for mounting the power modules.

The structural grid has a depth sufficient to provide structural rigidity to the photovoltaic array. The position of the photovoltaic array is controlled by a two axis sun tracking servomechanism that keeps the solar radiation perpendicular to the photovoltaic array plane.

Such a large array of concentrated photovoltaic power generating modules, positioned by a high power rotary servomechanism, is considered to be a very economic.

There are several problems with this approach. First, large metallic structural grids that have enough rigidity and dimensional accuracy are difficult to design and manufacture, which may limit the economic advantage of a large array. Assembling power generating modules to a large structural grid in the field may require individual alignment of each module to compensate for structural inaccuracy and deformations. Complex alignment procedures and test fixtures may be required because module alignment can not be carried out with a live system.

Second problem is that sun tracking of large structures cause significant changes in structural forces caused by gravity. Furthermore, wind load and temperature variation can also cause significant elastic deformations which can not be accounted for, leading to focus inaccuracy and conversion efficiency degradation.

Optical sensors mounted on the panel, feeding the sun tracking servomechanism, can only make corrections related to the location of the sensor. Averaging of several sensors mounted at different locations on the array may yield control instability issues and more tracking errors related to structural dynamic deformations.

The third problem is that even with powerful servomechanisms, position changes of a massive array is too slow for correcting dynamic errors created by wind, leading to more efficiency loss.

The fourth problem is that heat generated by the large number of photovoltaic cells arranged on a tilted plane, have to be effectively dissipated to the environment by natural convection and wind that is characterized by very low speed and arbitrary direction when the generator is installed in a desert area. The heat sink has to be robust enough to withstand desert storms and needs to be maintenance free.

The fifth problem is that significant voltage and current differences may exist between power generating modules due to photovoltaic cell manufacturing process variations, module misalignment, partial cell failure or shadowing. These differences may cause efficiency loss when the modules are electrically combined to a grid.

### SUMMARY OF THE INVENTION

A first object of this invention is to provide a solar energy generator module for a modular photovoltaic array, utilizing sensors, digital controllers and digital communication means for monitoring and digitally communicating a variety of physical parameters from each module to a central computer. This information can be utilized to monitor module health for maintenance purposes, and can also be used as a position input for the primary servomechanism control algorithm.

It is a related object to provide a low cost power line or wireless communication device (e.g. IEEE 802.15 ZIGBEE alliance communication protocol) in each power generating module, forming a reliable communication network connecting between each power generating module and the primary controller computer.

After initial sky scan, focus data can be used to generate alignment data for each module that can be used for initial module alignment.

The second object of the present invention is to provide a modular photovoltaic array, with self aligning power generating modules designed to correct focus misalignment caused by static and dynamic structural deformations of the array, by utilizing a secondary servomechanism for each power generating module. Thus automatically keeping the photovoltaic cells focused and fully illuminated.

The third object is to provide a low cost heat sink specially optimized for dissipating heat from a photovoltaic cell to the environment by natural convection and by low speed wind when installed in a large photovoltaic array.

The forth object is to provide a power converter within each power generating module that converts the voltage and current generated by the module for maximum power transfer to an electrical grid.

These objects, as well as others, that will become apparent upon reference to the following detailed description and accompanying drawings, are accomplished by a new solar energy generating module, comprised of a multiple solar concentrating devices focusing solar radiation on photovoltaic cells.

Each power generating module supports a concentrating assembly, having multiple lenses or reflectors. Each lens or reflector is concentrating solar radiation on a photovoltaic cell to generate electrical power. Each photovoltaic cell is thermally attached to a heat sink specially designed to dissipate excessive heat from the photovoltaic cell to the environment by natural convection and by natural wind. The power generating module has good dimensional accuracy and sufficient structural rigidity to keep the concentrating assembly in one plane.

Focus misalignment due to panel structural deformations and tracking errors is measured by sensors feeding a digital controller within each power generating module. Focus data is communicated to a central controller together with other physical parameters such as cell temperature and conversion efficiency, this data is being used for maintenance and control functions. After initial sky scan, alignment data for each module can be generated.

A multitude of secondary servomechanisms can dynamically control the position of each power generating module relative to the structural grid, dynamically correcting structural deformations thus keeping all photovoltaic cells in the array focused and fully illuminated by concentrated solar radiation.

A switching power converter within each module controls the electrical output to the electrical grid for maximum power transfer from the module.

The concentrating device can be in form of a concentrating lens or a reflector mounted in a housing that supports a photovoltaic cell therein.

A heat sink is thermally connected to the photovoltaic cell to dissipate excessive heat to the environment. An optional transparent cover protect the sensitive parts of the module from the environment. Positive and negative contacts are connected to the cell to transfer the electrical energy to an electrical grid.

A multitude of such lenses, heat sinks and photovoltaic cells are mounted in a rectangular housing having good rigidity and structural accuracy forming a power generating module with significant electrical power.

An optional switching converter within the power generating module convert the electrical voltage and current generated by the module thus dynamically adapting the load to the cells for transferring maximum power to the electrical grid.

The housing which supports the lens assembly, the photovoltaic cells and heat sinks is installed in a multi module panel being formed of a structural grid. A two axis sun tracking servomechanism moves the panel and keeps the lens optical axis directed to the sun during the day. Sensors and digital controllers are located within each module, communicating focus and other physical parameters to a central controller.

After initial assembly of the power generating modules into the planar structural grid, sky scan is initialized and focus data is collected by a central controller from all power generating modules through a digital communication network.

After installation and initial sky scan, the collected focus data is used to generate alignment instruction for each power generating module. This one time alignment can be done manually during the night.

With relatively small panels, only fine alignment will be required and one time manual alignment will be sufficient after installation or when a module is replaced due to failure. The digital communication can be implemented by a dedicated wire network, power line network, or by wireless network.

Many low cost wireless networking solutions designed for short range communication exist for control applications. Meshed networks are very popular for these applications. These solutions are commonly designed to work in an unlicensed spectrum and are suited to support large number of control nodes, each network node relaying information through its neighbors, thus information propagates and reach the destination.

In a preferred embodiment, IEEE802.15 ZIGBEE alliance communication protocol is utilized as a low cost short range wireless communication method implemented within each power generating module, operating in the unlicensed spectrum of 2.4 GHz and forming a wireless meshed communication network.

Data is being transmitted from each module and can be relayed through adjacent modules thus propagating across the solar panel to the central controller. Very low transmission power and small antenna are sufficient to carry out the communication because the range between modules is relatively small.

Large panels may need more frequent alignments of each module due to dynamic deformations of the structural grid. In this case a secondary servomechanism can be designed for each power generating module, dynamically correcting any focus misalignment for best efficiency performance.

Focus alignment data can be generated by specially designed light sensors that generate error signals when the concentrated solar radiation falls out of the photovoltaic cell borders, and these signals are used by the secondary servomechanism to keep the module directed to the sun for best efficiency.

The control circuitry as well as the servomechanism can be designed into the power generating module housing, powered by the common electrical grid, thus creating a self aligning, self powered, sealed module that is easily installed in the field and is easily replaceable in case of failure.

When such a self aligning module is used, the dimensional accuracy of the structural grid is non critical, hence its manufacturing cost is significantly reduced.

The heat generated by the photovoltaic cell subjected to concentrated solar radiation, according to the present invention, is dissipated to the environment by a new heat sink, comprised of a multiple metallic rods protruding from the perimeter of a relatively small heat spreader to which the photovoltaic cell in thermally attached. The rods are tilted out with a predetermined angle to form a diverging multi finger shape.

Each rod is designed to take a part of the heat load closely from the heat source; the heat is conducted along the rod and is dissipated from its surface to the environment. Hence the heat spreader dimensions and weight are minimal.

Heat dissipation from a rod is generally considered very effective due to the relatively low air speed at which turbulent flow begin to enhance heat transfer. The heat sink according to the present invention, substantially protrude from the back of the power generating module into the air. The rods are substantially separated from each other to minimize overall air flow resistance when the heat sinks are arrayed on a solar panel.

It has been discovered that a large number of heat sinks, in form of rods diverging from a small heat spreader, arrayed at the back side of a large solar panel, create a relatively thick heat exchanging air layer that flows easily thus effectively transferring heat from the photovoltaic cells to the environment even with natural convection and with very low wind speed.

The good heat exchanging efficiency together with minimum weight of the heat sink according to the present invention is very attractive for the design of concentrated solar power generating panels.

The number of rods, the tilt angle and rod dimensions can be optimized for minimizing air flow resistance together with maximum cooling efficiency.

The optimization process can take into account the large number of heat sinks influence on the air flow and air temperature at the low wind speed expected in a solar power plant field during a typical desert day.

Another advantage of the heat sink according to the present invention is that it is not sensitive to wind direction and it is robust enough to withstand desert storms without degradation.

In a preferred embodiment of the heat sink according to the present invention, a number of rods are arranged on the perimeter of a cylindrical heat spreader to allow low cost molding of the heat sink by a two part die. Each die part is conically shaped, having grooves on the surface. When the die parts are engaged, the grooves in each part combine to form a cavity for a rod.

This low cost manufacturing method allows for a large range of rod dimension selection without die parting issues and part extraction constrains that would exist with other heat sink configurations and that would limit their performance.

In another embodiment of the heat sink according to the present invention the heat sink is stamped out of a relatively thick metallic plate. The rods are being stamped out and bent to the required angle forming a multi rod heat sink, each rod having rectangular cross section.

It should be noted that many rod shapes, dimensions and any number of rods can be designed to carry out the heat sink design according to the present invention and there is no intent to limit the invention to those described in the drawings.

In another embodiment of the present invention, a reflector is concentrating solar radiation on a photovoltaic cell thermally attached to a metallic rod that penetrate through the transparent protective cover and dissipates excessive heat from the photovoltaic cell to the environment. A light weight heat pipe can be used instead of the metallic rod allowing for better heat dissipation with minimal weight and minimal shadowing. The heat pipe according to the present invention is a thin walled metallic pipe, vacuumed and filled with a small amount thermodynamic liquid. The heat pipe is perpendicular to the solar array plane that is kept directed to the sun by the primary servomechanism, thus the shadow by the heat pipe cross section on the reflector is minimal.

The orientation of the heat pipe in a solar array according to the present invention is such that the thermodynamic liquid evaporates at the low end of the pipe by the heat generated by the photovoltaic cell, the vapor flows to the upper parts of the pipe that are colder than the lower part, condenses and the liquid flows back by gravity force to the lower end of the pipe. Very high heat conductivity can be achieved leading to small temperature drop along the heat pipe even with significant length.

Heat pipes are considered to be very efficient light weight heat transfer devices and are extensively used in the electronic industry. The heat pipe according to the present invention is gravity assisted therefore no capillary liquid pumping is required, thus the cost of manufacturing the heat pipe is reduced.

The electrical DC voltage generated by each photovoltaic cell can be combined in series and parallel with other cells in the module thus providing significant electrical power. A high efficiency switching power converter automatically controls the module output voltage for maximum power transfer at all times even if part of the photovoltaic cells within the module are less efficient because of by dust, partial shadowing, lens damage, cell contamination or aging.

Power conversion within each module also compensate for temperature differences that are expected between different areas on the array, leading to efficiency variations.

Thus, a power generating module can automatically maximize its electrical output to the array grid at any time of its life span. A power generating module can be replaced with a new module at any time without matching issues.

### BRIEF DESCRIPTION OF THE DRAWINGS

FIG. 1 is perspective view showing the front of a solar energy panel according to the present invention.

FIG. 2 is perspective view showing the back of a solar energy panel according to the present invention.

FIG. 3 shows a Fresnel lens, concentrating solar radiation on a square photovoltaic cell mounted on a metallic plate heat sink

FIG. 4 is a perspective view of a power generating module with multiple concentrating lenses and multiple photovoltaic cells mounted in a common housing with a two axis rotary servomechanism.

FIG. 5 shows a square photovoltaic cell with four light sensitive devices mounted adjacent to the cell, generating focus alignment signals.

FIG. 6 is a side view and bottom view of a Conical Rod-Fin heat sink according to the present invention with round rods arranged on the perimeter of a round heat spreader.

FIG. 7 shows a Fresnel lens, concentrating solar radiation on a square photovoltaic cell mounted on conical rod fin heat sink supported by the module back plate.

FIG. 8 is an isometric view of a two part die for molding a heat sink according to the present invention, with rods arranged on the perimeter of a round heat spreader.

FIG. 9 shows a front view and bottom view of a heat sink stamped out of a metallic plate with the rods protruding from a square heat spreader, each rod being bent to the required angles.

FIG. 10 shows a front view and bottom view of a heat sink stamped out of a metallic plate with the rods protruding from a hexagonal heat spreader each rod being bent to the required angles.

FIG. 11 shows a reflector concentrating solar radiation on a photovoltaic cell thermally attached to a heat pipe penetrating through a transparent protective cover, dissipating excessive heat to the environment in front of the solar array.

### DETAILED DESCRIPTION OF THE PREFERRED EMBODIMENTS

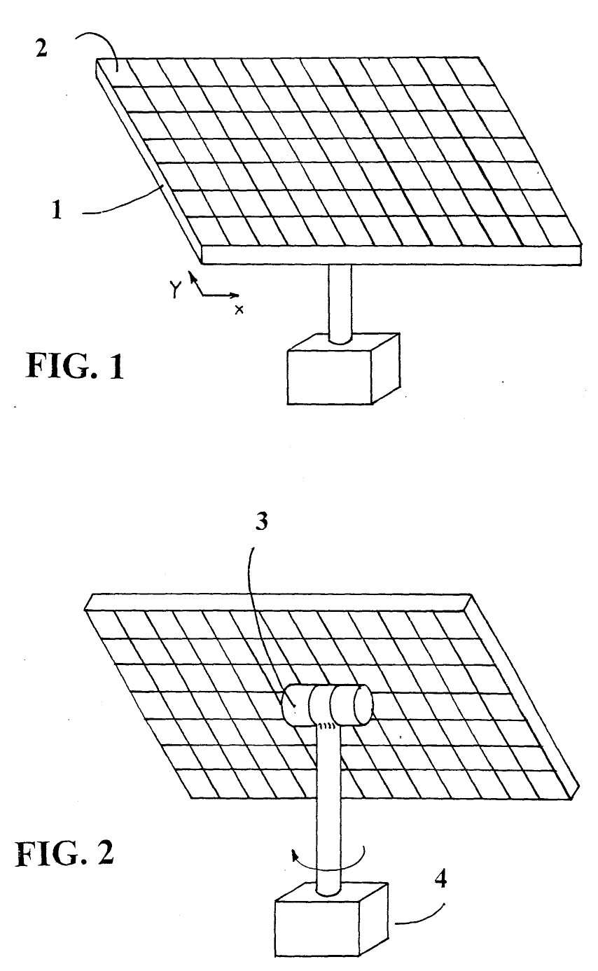

As illustrated in FIG. 1, a solar energy panel according to the present invention is comprised of a structural grid 1, with multiple power generating modules 2 installed in spaces within said structural grid.

As can be seen in FIG. 2, The sun tracking panel is positioned by two axis servomechanisms 3 & 4 to keep the concentrated solar radiation focused on the photovoltaic cells.

For each power generating module, the heat sink on which the photovoltaic cell is mounted is exposed to the environment to dissipate excessive heat that is generated by the cell. The heat sink can be formed as a flat plate as showed in FIG. 2 or have fins protruding to the back side of the panel.

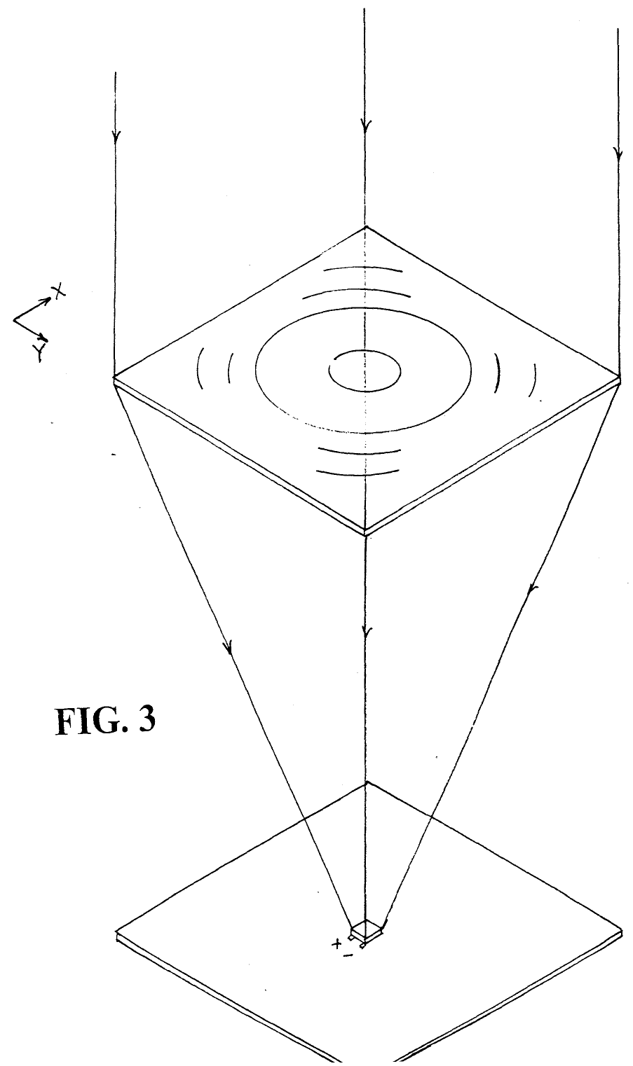

FIG. 3 shows a Fresnel lens concentrating solar radiation on a square photovoltaic cell mounted on a heat sink plate. The heat sink plate may or may not have fins, and its back side is exposed, dissipating heat to the environment. Electrical connections to the photovoltaic cell are provided, connected in serious and in parallel with other cells to optimally transfer the electrical energy to a power grid and to the load.

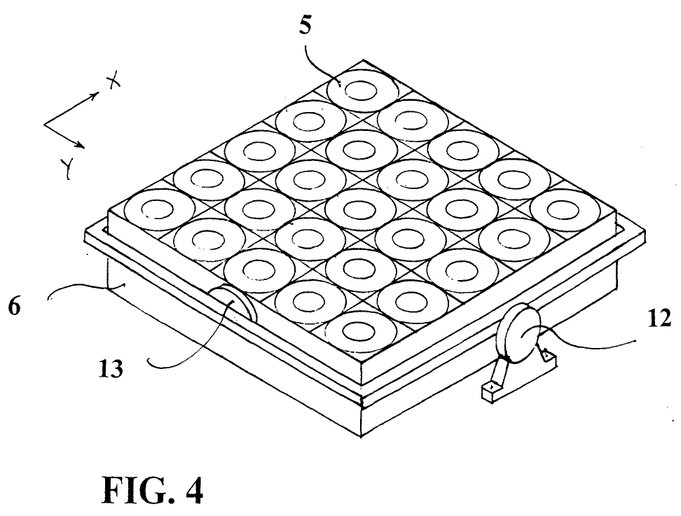

In FIG. 4, a multitude of lenses 5 and photovoltaic cells are combined into a common housing to form a power generating module having significant voltage and power generating capability. The common housing 6 has sufficient structural accuracy and rigidity to keep all lenses aligned together with a common optical axis.

A digital controller and a communication device are mounted in the housing, communicating physical parameters to a central controller, communicating focus alignment data that can be used to generate manual alignment instructions after initial sky scan when no secondary servomechanism is implemented, such as in the case of small panels. Other physical parameters are also communicated to the central controller for maintenance purposes (e.g. power generating module degradation or failure detection).

In one embodiment of the present invention, a secondary servomechanism is mounted in the housing, capable of limited two axis X-Y movements of the lens assembly relative to the power generating module, correcting structure deformations and thus positioning the concentrated solar illumination spot right on the cell.

In another embodiment of the present invention, a secondary servomechanism is mounted in the housing, capable of limited two axis rotational movements of the lens assembly relative to the power generating module, thus positioning the concentrated solar illumination spot right on the photovoltaic cell.

In a third embodiment of the present invention, a secondary servomechanism motors 12, 13 are mounted on the module housing, capable of two axis rotational movements of the power generating module housing relative to the structural grid, thus positioning the concentrated solar illumination spot right on the cell.

A self aligning, communicating, power generating module according to the present invention allows for reduced overall panel cost as well as easier installation and better sun tracking accuracy.

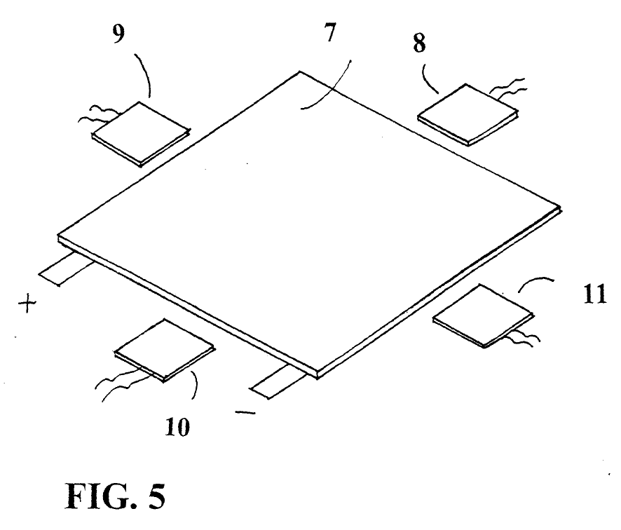

FIG. 5 shows a photovoltaic cell 7 with four light sensitive devices 8-11 mounted adjacent to the cell, generating focus correction signals.

Generally, when balance is achieved between two opposite light sensing devices it is an indication for well centered solar illumination of the cell. Any out of balance will generate correction signals for the servomechanism control algorithm.

Many methods can be used to carry out focus sensing and alignment according to the present invention and there is no intent to limit the invention to those described.

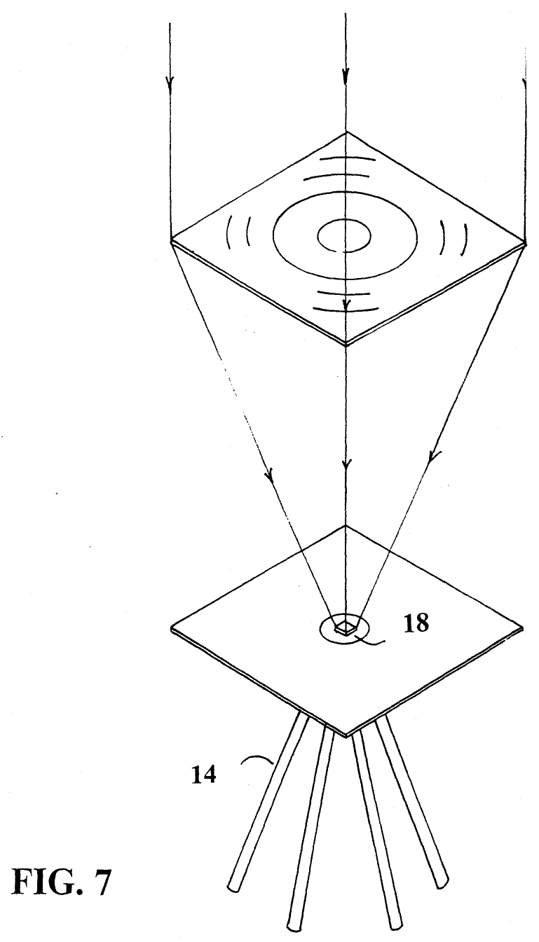

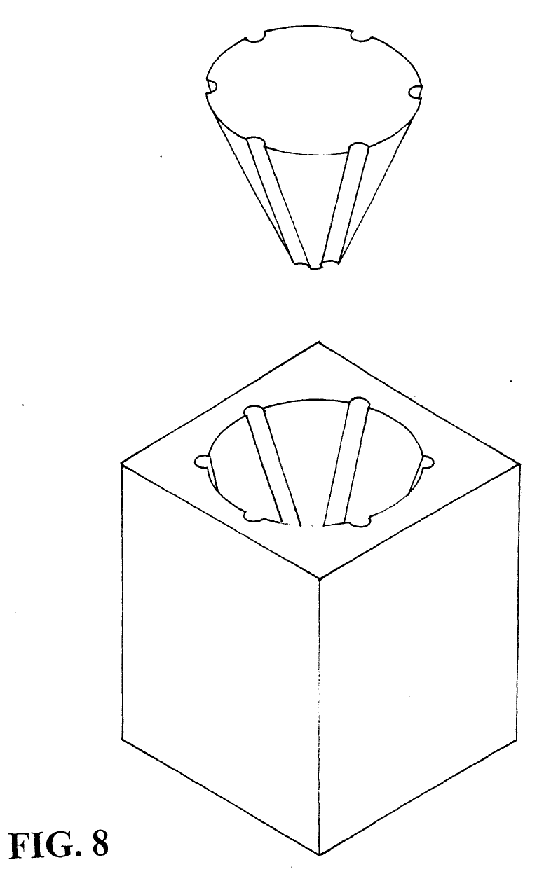

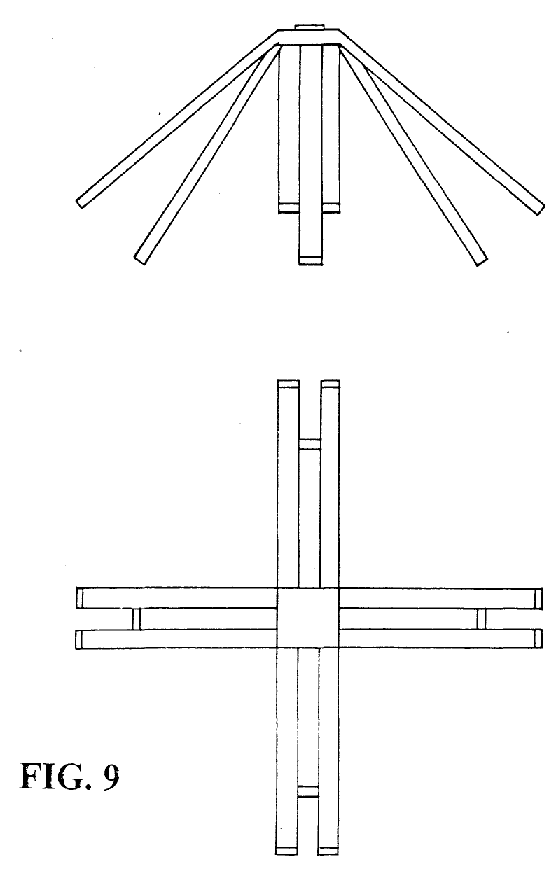

In FIG. 7, according to a preferred embodiment of the present invention, the heat generated by the photovoltaic cell 18 subjected to concentrated solar radiation, is dissipated to the environment by a new multi finger heat sink 14.

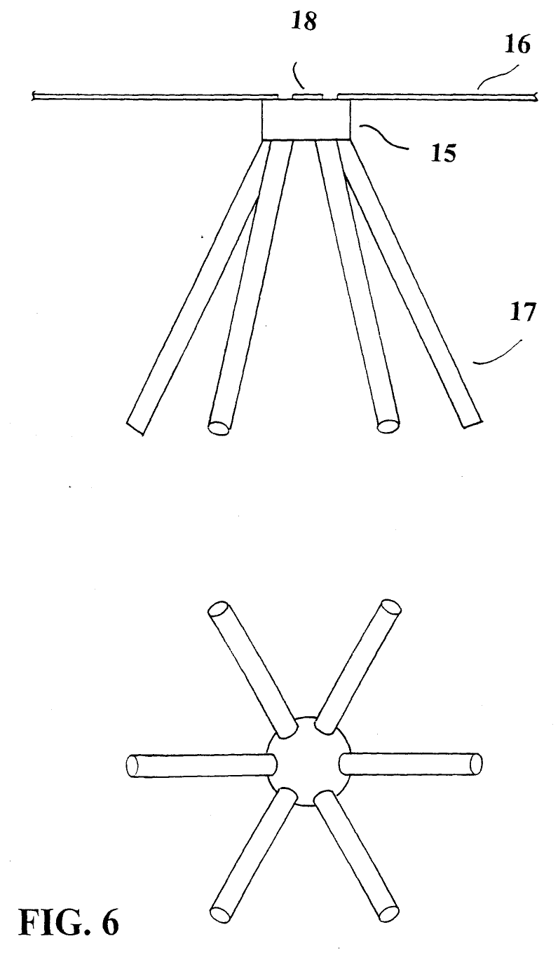

As can be seen in FIG. 6, the heat sink is comprised of multiple metallic rods 17 protruding from the perimeter of a relatively small heat spreader 15 to which the photovoltaic cell 18 in thermally attached. The rods are tilted out with a predetermined angle to form a diverging conical shape.

The heat spreader is supported by the back plate 16 of the power generating module housing.

Each rod is designed to take a part of the heat load closely from the heat source; the heat is conducted along the rod and is dissipated from its surface to the environment. Hence the heat spreader dimensions and weight are minimal.

The heat sink is unusually designed to occupy a significant thick air layer behind the solar panel while keeping significant distance between the rods, thus allowing efficient heat exchange with the environment even with very low wind speed.

The number of rods, the tilt angle and rod dimensions can be optimized for minimum air flow resistance together with maximum cooling efficiency.

A preferred embodiment of the heat sink according to the present invention sowed in FIG. 6, with the rods arranged on the perimeter of a cylindrical heat spreader.

The rods can optionally be arranged on the perimeter of a rectangular box heat spreader with the rods forming a pyramid.

The rods can also be combined together to form a cone or a pyramid with the top flattened to form a plane on which the photovoltaic cell is thermally attached. In this case the heat spreader is created by the rods converging together at the top of the cone or the pyramid.

The rods can also be zigzagged and every other rod can be tilted in a different angle to form a cone within a cone or a pyramid within a pyramid thus separating the rods from each other, allowing better air flow between the rods.

Low cost two part molding die for a conical heat sink according to the present invention is showed in FIG. 7. Each die part is conically shaped, having grooves on the cone surface. When the die parts are engaged, the mating grooves combine to form a cavity for a single rod being part of the heat sink.

This low cost manufacturing method is adaptable for all the heat sink configurations according to the present invention and allow for a wide range of rod dimensions selection without die parting difficulties and part extraction constrains that would exist with other heat sink configurations and that would limit their performance.

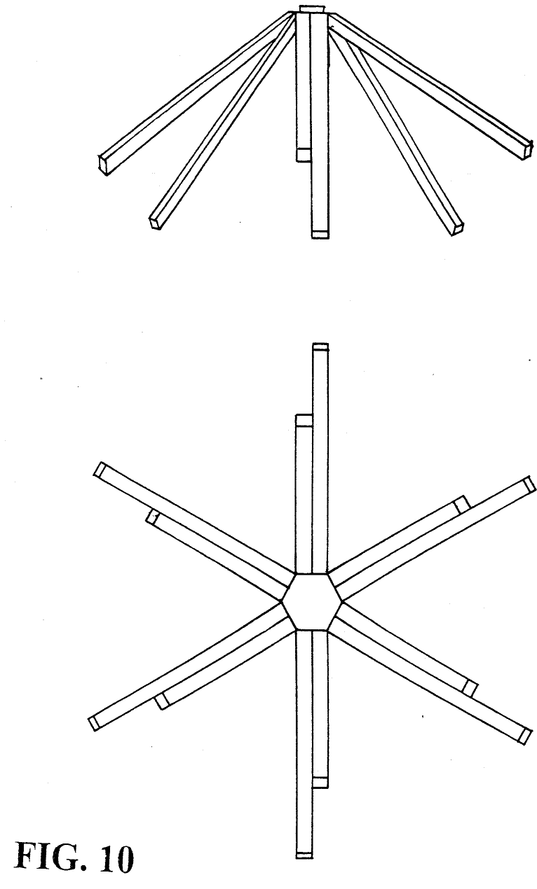

In another low cost embodiment of the heat sink according to the present invention, the heat sink is stamped out of a relatively thick metallic plate and the rods are bent to the required angle as showed in FIG. 9 that has square heat spreader and FIG. 10 that has hexagonal heat spreader.

The heat sink can be shaped in a form that allows stamping of the heat sink in one action from a square, rectangular or hexagonal plate without any scrap, leading to even better heat conduction and further cost reduction.

The photovoltaic cells within each module are connected in series and parallel, feeding a high efficiency switching power converter installed within each module, that converts the voltage while monitoring the current and controlling the switching characteristics to continuously achieve maximum power transfer to the grid. The grid may be designed with AC or DC voltage as required by the load. Many methods for designing high efficiency, low cost, compact power converters at high switching frequency are available and can easily be integrated into the power generating module. A specially designed controller monitors the output voltage and current and dynamically varies switching frequency and/or duty cycle to achieve maximum power transfer.

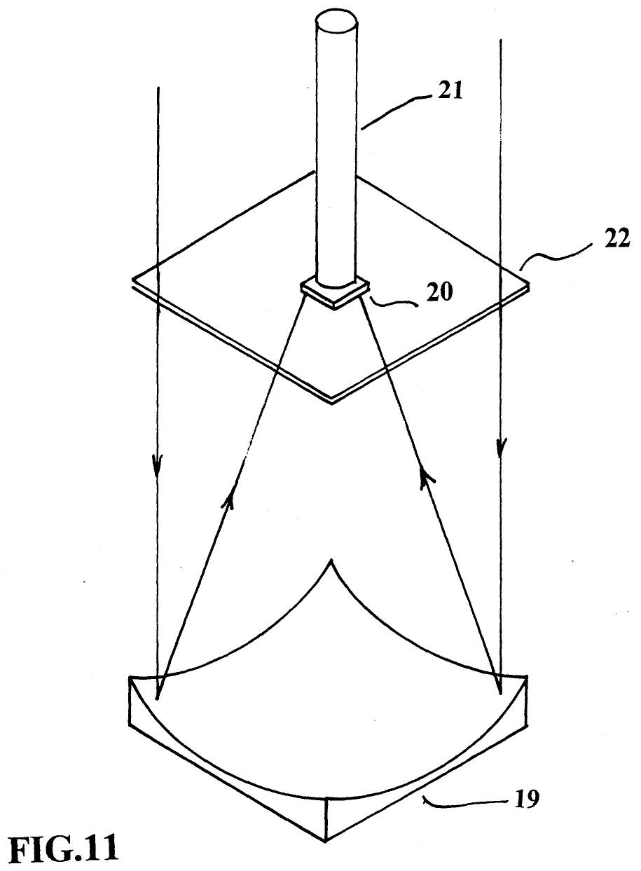

FIG. 11 shows another embodiment of the present invention, in which a reflector 19 is concentrating solar radiation on a photovoltaic cell 20, thermally attached to a heat pipe 21 that penetrates through the transparent protective cover 22 of the power generating module and dissipates excessive heat from the photovoltaic cell to the environment in front of the solar array by natural convection and by wind. The heat pipe according to the present invention is a thin walled metallic pipe, vacuumed and filled with a small amount thermodynamic liquid. The photovoltaic cell is thermally attached to the lower part of the pipe, evaporating the thermodynamic liquid, the vapor flows to the upper parts of the pipe that are colder than the lower part, condenses and the liquid flows back by gravity force to the lower end of the pipe.

A heat pipe with significant length, when used to dissipate heat from a concentrated photovoltaic cell in a large array, has been discovered to be very effective because it creates a relatively thick heat exchanging air layer in front of the array, that has minimal resistance to air flow, thus allowing for very effective heat dissipation even with very low wind velocity or by natural convection.

Many shapes methods and manufacturing processes can be used to carry out the heat sink, the communication network, the module alignment mechanism, the servomechanisms and converter circuits according to the present invention and there is no intention to limit the invention to those described.

What we claim is:

1. A photovoltaic array for generating electric power from concentrated solar radiation comprising;
a planar structural grid, being defined by a multiplicity of structural members connected to one another and defining spaces between the structural members for a multitude of power generating modules, said structural grid positioned by a two axis primary servomechanism to keep incident solar radiation perpendicular to the plane of the structural grid,
a concentrator assembly comprised of multiple of solar concentrating devices, directly supported by structural members having sufficient structural accuracy and rigidity to keep all the concentrating devices within the concentrator assembly optically aligned with a common optical axis,
a multitude of photovoltaic cells mounted on heat sinks receiving concentrated solar radiation from the concentrating devices,
a housing supporting said concentrator assemblies, said photovoltaic cells and said heat sinks forming a photovoltaic power generating module,
a secondary servomechanism designed to independently align each power generating module for correcting structural grid deformations, misalignment and tracking errors, keeping solar radiation focused on the photovoltaic cell,
whereby said concentrator assemblies, said structural members, said structural grid, said power generating module, said primary servomechanism, said secondary servomechanism, said photovoltaic cells and said heat sinks have an integrated relationship.

2. The photovoltaic array of claim 1 wherein each power generating module contains mechanical and electrical parts required for the secondary servomechanism, forming an integrated self aligning photovoltaic power generating module.

3. The photovoltaic array of claim 1 wherein the concentrating device is a lens.

4. The photovoltaic array of claim 1 wherein the concentrating device is a reflector.

5. The photovoltaic array of claim 2 wherein each photovoltaic power generating module contains the mechanical and electrical parts required for operating the secondary servomechanism, being designed for dynamically positioning the concentrator assembly relative to the power generating module housing, keeping the photovoltaic cell aligned with the concentrated solar illumination area.

6. The photovoltaic array of claim 2 wherein each photovoltaic power generating module contain the mechanical and electrical parts required for the secondary servomechanism, being designed to align the power generating module relative to the structural grid keeping the photovoltaic cell aligned with the concentrated solar illumination area.

7. The photovoltaic array of claim 2 wherein a transparent cover protect the concentrating device, photovoltaic cell and other sensitive parts of the power generating module from the environment, forming an integrated, sealed self aligning photovoltaic power generating module.

8. The photovoltaic array of claim 2 wherein each power generating module contain sensors and digital control designed to monitor module physical parameters and to control the module position.

9. The photovoltaic array of claim 8 wherein digital communication means are embedded in each photovoltaic power generating module, forming a communication network connecting between each photovoltaic power generating module and a central controller, digitally communicating a variety of physical parameters and control signals with the central controller.

10. The photovoltaic array of claim 8 wherein digital communication is embedded in each photovoltaic power generating module utilizing the electrical power grid as a communication media, forming a communication network, digitally communicating a variety of physical parameters and control signals to a central controller.

11. The photovoltaic array of claim 8 wherein a digital wireless communication is embedded in each power generating module, forming a communication network connecting between each photovoltaic power generating module and the central controller, digitally communicating a variety of physical status parameters and control signals with a central controller.

12. The photovoltaic array of claim 11 wherein the digital wireless communication network is implemented according to the IEEE802.15 ZIGBEE alliance protocol.

13. The photovoltaic array of claim 1 wherein the photovoltaic cells within each power generating module are connected in series and parallel, feeding a switching power inverting device that is mounted within each power generating module, designed to regulate the electrical output of the power generating module for maximum power transfer to an electrical grid.

14. The photovoltaic array of claim 1 wherein light sensitive devices within each power generating module, generate focus and alignment error signals.

15. The photovoltaic array of claim 1 wherein the heat sinks, is having multiple metallic rods protruding from a heat spreader base into the space in the back of the Photovoltaic Array panel, each rod being tilted out in an angle forming a diverging shape multi finger heat sink, the Photovoltaic cell is thermally attached to the heat spreader.

16. The photovoltaic array of claim 15 wherein each heat sink is formed by multiple metallic rods protruding in a zigzagged manner from the perimeter of a heat spreader.

17. The photovoltaic array of claim 15 wherein each heat sink is formed by multiple metallic rods, each rod is having non constant cross section area.

18. A die for molding the heat sink of claim 15 formed of a male conical part and a female conical part, having grooves on the face of at least one part of the die, forming multiple cavities for molding the rods, both parts can be engaged to form a die for molding a multi rod heat sink with a heat spreader.

19. The photovoltaic array of claim 15 wherein the heat sink is manufactured by stamping a heat spreader and rods out of a metallic plate and bending of the heat sink fins to required angle.

20. The photovoltaic array of claim 15 wherein at least one Photovoltaic Cell is thermally attached to a gravity assisted heat pipe located in the back of the array, the thermodynamic fluid in the heat pipe flows by force of gravity and wetting the heat pipe part at which the Photovoltaic Cell is attached, the heat pipe is having sheet metal fins thermally attached to it thus dissipating heat to the environment.
